(19) United States
(12) Patent Application Publication
(10) Pub. No.: US 2026/0136858 A1
(43) Pub. Date: May 14, 2026

(54) ATOMIC LAYER ETCHING METHOD

(71) Applicant: ELECTRONICS AND TELECOMMUNICATIONS RESEARCH INSTITUTE, Daejeon (KR)

(72) Inventors: Seong Hyun LEE, Daejeon (KR); Dongwoo SUH, Daejeon (KR); Minkyun SOHN, Daejeon (KR); Sang Hoon KIM, Daejeon (KR); Jieun KIM, Daejeon (KR); Min-A PARK, Daejeon (KR); Jaeseoung PARK, Daejeon (KR); Jeong Woo PARK, Daejeon (KR); Sun Kyu JUNG, Daejeon (KR)

(21) Appl. No.: 19/289,368

(22) Filed: Aug. 4, 2025

(30) Foreign Application Priority Data
Nov. 8, 2024 (KR) 10-2024-0158153
Apr. 10, 2025 (KR) 10-2025-0046963

(51) Int. Cl. H01L 21/3213; H01L 21/3065

(52) U.S. Cl. CPC H10P 50/267; H10P 50/242

(57) ABSTRACT

Provided is an atomic layer etching method. The atomic layer etching method includes a step of providing a substrate, a modification step of modifying a surface layer of the substrate, and an etching step of removing the modified surface layer of the substrate. The modification step includes a step of adsorbing a first gas onto the substrate, and a step of adsorbing a second gas onto the substrate. The second gas is supplied after being radicalized by plasma.

### CROSS-REFERENCE TO RELATED APPLICATIONS

This U.S. non-provisional patent application claims priority under 35 U.S.C. § 119 of Korean Patent Application Nos. 10-2024-0158153, filed on Nov. 8, 2024, and 10-2025-0046963, filed on Apr. 10, 2025, the entire contents of which are hereby incorporated by reference.

### BACKGROUND

### 1. Field of the Invention

The present disclosure herein relates to an atomic layer etching method, and more particularly, to an atomic layer etching method for a semiconductor device including a 3D structure.

### 2. Description of Related Art

As the trend toward ultra-high integration and extreme miniaturization of semiconductor devices advances, both the thickness of thin films and the line width (Critical Dimension, CD) of patterns are being scaled down to increasingly smaller dimensions. For example, in the case of a DRAM device, a conductive film or a dielectric film constituting a transistor is thinned down, and the line width is also reduced to 5 nm or less. In the fabrication of a semiconductor device having such an ultra-thin and ultra-fine pattern, precise control of dimensions becomes increasingly difficult, and issues such as surface damage may occur. Accordingly, there is a growing demand for atomic-scale processing in deposition processes and etching processes.

Furthermore, as the trend toward ultra-high integration and extreme miniaturization of semiconductor devices advances, device architectures employing 3D structures, such as Gate-All-Around Field Effect Transistors (GAA-FETs) and Complementary Field Effect Transistors (CFETs), are becoming more prevalent. In the manufacturing of semiconductor devices, atomic layer modification and etching are essential. In particular, in semiconductor devices having 3D structures, atomic layer modification and etching are more challenging than in conventional 2D structures due to their complex geometries. Therefore, there is an increasing need for a process that may perform atomic layer modification and etching with greater accuracy and stability in semiconductor devices having complex structures.

### SUMMARY

The present disclosure provides an atomic layer etching method capable of uniformly and efficiently modifying and etching an atomic layer of a semiconductor device.

The problem to be solved by the inventive concept is not limited to the aforementioned issues, and other problems not mentioned herein will be clearly understood by those skilled in the art from the description below.

An embodiment of the inventive concept provides an atomic layer etching method including: a step of providing a substrate; a modification step of modifying a surface layer of the substrate; and an etching step of removing the modified surface layer of the substrate, wherein the modification step includes: a step of adsorbing a first gas onto the substrate; and a step of adsorbing a second gas onto the substrate, wherein the second gas is supplied after being radicalized by plasma.

In an embodiment, the atomic layer etching method may further include a purging step performed before the etching step, wherein the purging step may include purging residual reactants of the modification step.

In an embodiment, the modification step, the purging step, and the etching step may be repeatedly performed in sequence.

In an embodiment, the step of the adsorbing the second gas may be performed at a pressure in a range of about 10⁻³ Torr to about 10⁻⁴ Torr.

In an embodiment, the step of the adsorbing the first gas may be performed at a pressure in a range of about 10⁰ Torr to about 10¹ Torr.

In an embodiment, the first gas may include at least one of O₂, H₂, NH₃, HF, CF₄, NF₃, SF₆, CHF₃, Cl₂, and BCl₃.

In an embodiment, the gas radicalized from the second gas may include at least one of Cl* and F*.

In an embodiment, the substrate may have a pattern, wherein the pattern may include a plurality of three-dimensional structures spaced apart from each other on the substrate, in the modification step, the first gas may modify a portion of surfaces of the pattern, and in the modification step, the second gas may modify remaining surfaces of the pattern.

In an embodiment, the remaining surfaces of the pattern may include facing surfaces of two three-dimensional structures adjacent to each other among the three-dimensional structures.

In an embodiment, the etching step may include: a step of injecting a third gas to react with a portion of the modified surface layer; and a step of injecting a fourth gas to react with a remaining portion of the modified surface layer wherein the fourth gas is supplied after being radicalized by plasma.

In an embodiment, the etching step may include injecting a fifth gas to etch the modified surface layer, wherein the fifth gas may include a gas generated by vaporizing a precursor.

In an embodiment of the inventive concept, an atomic layer etching method includes: a step of providing a substrate into a chamber; and a step of etching first and second surfaces of the substrate, wherein the step of the etching the first and second surfaces of the substrate comprises an adsorption cycle and a removal cycle, wherein the adsorption cycle includes: a step of adsorbing a first gas onto the first surfaces of the substrate to form a first reaction layer; and a step of adsorbing a second gas onto the second surfaces of the substrate to form a second reaction layer, and wherein the removal cycle includes: a step of supplying a third gas to the substrate to etch part of the first and second reaction layers; and a step of supplying a fourth gas to the substrate to etch remaining parts of the first and second reaction layers, wherein the second gas and the fourth gas are radicalized gases, and the step of the forming the second reaction layer is performed at a pressure lower than that in the step of the forming the first reaction layer.

In an embodiment, the substrate may have a pattern comprising at least one trench.

In an embodiment, the first surfaces may include a top surface of the substrate, and the second surfaces may include inner surfaces of the trench.

In an embodiment, the substrate may have a pattern, wherein the pattern may include a plurality of three-dimensional structures spaced apart from each other on the substrate, and the three-dimensional structures may be spaced apart from each other and laminated on the substrate.

In an embodiment, the atomic layer etching method may further include a step of purging residual reactants of the first and second gases, wherein the purging step of purging the reactants of the first and second gases may be performed between the adsorption cycle and the removal cycle.

In an embodiment, the first gas and the third gas may be non-radicalized gases.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view illustrating an atomic layer etching apparatus according to embodiments of the inventive concept;

FIG. 2 is a flowchart explaining an atomic layer etching method according to embodiments of the inventive concept;

FIG. 3 is a process flow diagram illustrating the atomic layer etching method according to embodiments of the inventive concept;

FIGS. 4 to 7 are cross-sectional views illustrating an atomic layer etching method according to embodiments of the inventive concept;

FIG. 8 is a process flow diagram illustrating the atomic layer etching method according to embodiments of the inventive concept; and

FIG. 9 is a cross-sectional view illustrating an atomic layer etching method according to embodiments of the inventive concept.

### DETAILED DESCRIPTION OF THE INVENTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. The thickness and the ratio and the dimension of the element are exaggerated for effective description of the technical contents. As used herein, the term “and/or” includes any and all combinations of one or more of the associated listed items.

In order to sufficiently understand the configuration and effect of the present invention, some embodiments of the present invention will be described with reference to the accompanying drawings. The present disclosure may, however, be embodied in different forms and should not be construed as limited to the embodiments set forth herein. Rather, the exemplary embodiments are provided only to disclose the present invention and let those skilled in the art fully know the scope of the present invention.

In the following description, the technical terms are used only for explaining a specific exemplary embodiment while not limiting the present invention. In this specification, the singular forms include the plural forms as well, unless the context clearly indicates otherwise. The meaning of ‘comprises’ and/or ‘comprising’ specifies a component, an operation and/or an element does not exclude other components, operations and/or elements. Since preferred embodiments are provided below, the order of the reference numerals given in the description is not limited thereto.

In the present specification, unless otherwise defined, technical and scientific terms are used in the sense commonly understood by those skilled in the art to which the inventive concept pertains. Descriptions of known functions and configurations that may unnecessarily obscure the gist of the inventive concept in the following description and the accompanying drawings will be omitted.

Like reference numerals throughout the specification may refer to the same components. Unless terms used in embodiments of the present invention are differently defined, the terms may be construed as meanings that are commonly known to a person skilled in the art.

Hereinafter, an atomic layer etching method according to the inventive concept will be described with reference to the drawings.

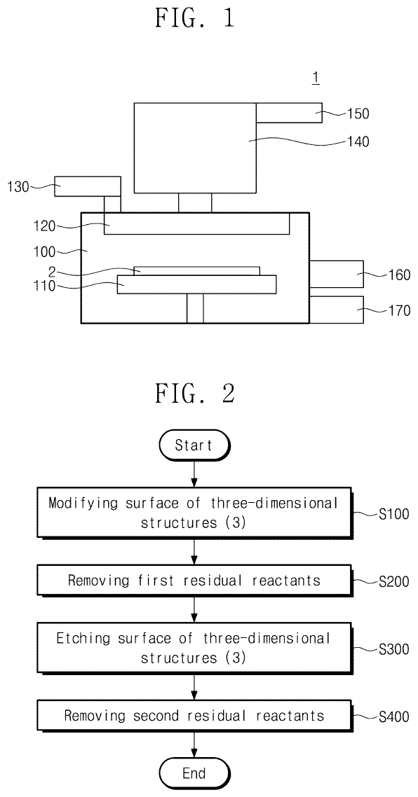

FIG. 1 is a cross-sectional view illustrating an atomic layer etching apparatus according to embodiments of the inventive concept. Referring to FIG. 1, an atomic layer etching apparatus 1 is provided. The atomic layer etching apparatus 1 may etch various targets. For example, the atomic layer etching apparatus 1 may etch a substrate or a mask. In one example, the atomic layer etching apparatus 1 may etch a substrate including a pattern. More specifically, the atomic layer etching apparatus 1 may etch a three-dimensional structure on the substrate. In this case, the substrate and the three-dimensional structure may refer to components of a semiconductor device having a three-dimensional structure. For example, the semiconductor device may include a Gate-All-Around Field Effect Transistor (GAA-FET) and a Complementary Field Effect Transistor (CFET). The three-dimensional structures may be provided in plurality. In one example, the three-dimensional structures may refer to semiconductor patterns of semiconductor device having the three-dimensional structure, although the inventive concept is not limited thereto. An etching target of the atomic layer etching apparatus 1 is not limited to the above examples, however, for convenience of explanation, in FIG. 1, it is assumed that the atomic layer etching apparatus 1 etches a surface layer of a substrate 2 having a pattern. In the present specification, the surface layer of the etching target may refer to an atomic layer exposed on a surface of the etching target of the atomic layers. An atomic layer etching process (ALE) may be performed on the atomic layer etching apparatus 1. In the present specification, the atomic layer etching process may refer to an etching process including at least one surface modification step for modifying the surface of the etching target and at least one etching step for removing the modified surface layer of the etching target. More specifically, the surface modification step may refer to a step of modifying the surface layer of the etching target. The surface modification step may include performing chemical treatment on the surface layer of the etching target. The chemical treatment may refer to changing chemical or physical properties of the surface layer by binding or adsorbing chemical substances to the surface layer of the etching target. The atomic layer etching apparatus 1 may include a chamber 100, a support 110, a showerhead 120, a first gas inlet 130, a plasma generator 140, a second gas inlet 150, a first pressure controller 160, and a second pressure controller 170.

The chamber 100 may be a space in which an etching process for the substrate 2 is performed. The chamber 100 may be empty. In other words, the chamber 100 may include a hollow internal space. In the present specification, the “interior” and “internal space” of the chamber 100 may be used interchangeably to refer to a space in which the etching process of the substrate 2 is performed inside the chamber 100. The substrate 2, which is the etching target, may be provided in the internal space of the chamber 100. Although not shown, a gate through which the substrate 2 is loaded into and unloaded from the chamber 100 may be provided on one side of the chamber 100. More specifically, the substrate 2 may be loaded from the outside through the gate and placed in the internal space of the chamber 100.

The support 110 may be provided in the internal space of the chamber 100. The support 110 may include a plate portion having a flat shape and a support shaft that supports the plate portion. For example, the support shaft may be vertically connected to a bottom surface of the plate portion. Although not illustrated, the support shaft may penetrate through a bottom surface of the chamber 100. The support shaft may be connected to a driving unit (not shown) outside the chamber 100 and may be configured to ascend or descend and/or rotate the plate portion. A heater (not shown) may be provided inside the plate portion. The heater may control the temperature of the substrate 2 placed on a top surface of the plate portion.

The showerhead 120 may be provided in an upper portion of the internal space of the chamber 100. More specifically, the chamber 100 may have a structure of which at least a portion of a top surface is opened. The showerhead 120 may be disposed in the upper portion of the internal space of the chamber 100. The showerhead 120 may cover the opened top surface of the chamber 100. In other words, the internal space of the chamber 100 may be closed by the showerhead 120. The showerhead 120 may transfer gases introduced into the showerhead 120 inside the chamber 100. The introduced gases may be uniformly sprayed into the internal space of the chamber 100 by the showerhead 120. In one example, the showerhead 120 may include a spray plate having a plurality of etching gas injection ports.

The first gas inlet 130 may be provided on the top surface of the chamber 100. The first gas inlet 130 may be connected to the chamber 100. In the present specification, the first gas inlet 130 may refer to a supply unit for supplying a first gas into the internal space of the chamber 100.

The plasma generator 140 may be connected to the chamber 100. In one example, the plasma generator 140 may be spaced apart from the first gas inlet 130 on the top surface of the chamber 100. The second gas inlet 150 may be connected to the plasma generator 140. In the present specification, the second gas inlet 150 may refer to a supply unit for supplying a second gas into the internal space of the chamber 100. In one example, the second gas inlet 150 may be provided on one side surface of the plasma generator 140, however the inventive concept is not limited thereto. The plasma generator 140 may radicalize the second gas and supply it into the internal space of the chamber 100. The plasma generator 140 may include a remote plasma generation unit. In one example, the remote plasma generation unit may use a Capacitor Coupled Plasma (CCP) method or an Inductively Coupled Plasma (ICP) method. In the present specification, the remote plasma generation unit may refer to a device configured to generate plasma in a space physically separated from the internal space of the chamber 100. Since the plasma generator 140 includes the remote plasma generation unit, the plasma generator 140 may supply only radical gas between electrons, ions, and radical gas generated inside the plasma generator 140, into the internal space of the chamber 100.

The first gas inlet 130 and the plasma generator 140 may be connected to the showerhead 120. The showerhead 120 may transfer the first gas supplied through the first gas inlet 130 into the internal space of the chamber 100. The showerhead 120 may also transfer the radicalized second gas supplied through the second gas inlet 150 and the plasma generator 140 into the internal space of the chamber 100.

The first pressure controller 160 and the second pressure controller 170 may be provided on one side surface of the chamber 100. In one example, the first pressure controller 160 and the second pressure controller 170 may be provided on a lower portion of the one side surface of the chamber 100. The first pressure controller 160 and the second pressure controller 170 may be spaced apart from each other at the lower portion of the side surface of the chamber 100. Each of the first pressure controller 160 and the second pressure controller 170 may include a pump and an exhaust port connected to the pump. The first pressure controller 160 and the second pressure controller 170 may serve to control the internal pressure of the chamber 100. In one example, the first pressure controller 160 and the second pressure controller 170 may reduce the pressure inside the chamber 100 to create an environment similar to a vacuum. More specifically, the first pressure controller 160 may adjust the internal space of the chamber 100 to a first pressure. The second pressure controller 170 may adjust the internal space of the chamber 100 to a second pressure. In the present specification, the first and second pressures may refer to a certain pressure range rather than specific pressure values. The first pressure may be higher than the second pressure. For example, the first pressure may be in the range of about 10⁰ Torr to about 10¹ Torr. The second pressure may be in the range of about 10⁻³ Torr to about 10⁻⁴ Torr.

The substrate 2 may include a metal or a metal compound. The substrate 2 may include at least one of copper (Cu), chromium (Cr), nickel (Ni), aluminum (Al), or other metals, or alloys thereof. In another embodiment, the substrate 2 may include silicon (Si). For example, the substrate 2 may include a silicon wafer. The substrate 2 may include a pattern formed on the substrate 2.

Although not illustrated, the atomic layer etching apparatus 1 may include a controller. The controller may serve to control the overall operation of the atomic layer etching apparatus 1. In one embodiment, the controller may control operations of the chamber 100, the first and second gas inlets 130 and 150, and the plasma generation part 140, and may set control parameters for the etching process through an interface with an operator. For example, the controller may include a central processing unit, memory, and input/output interfaces.

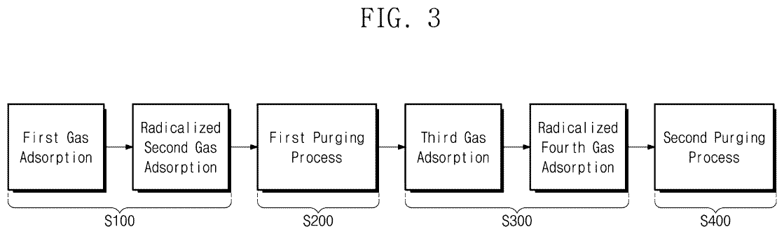

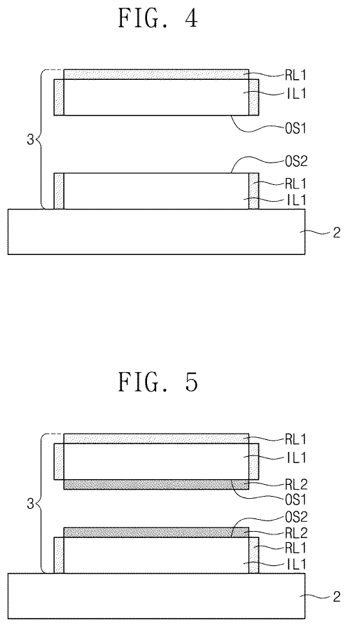

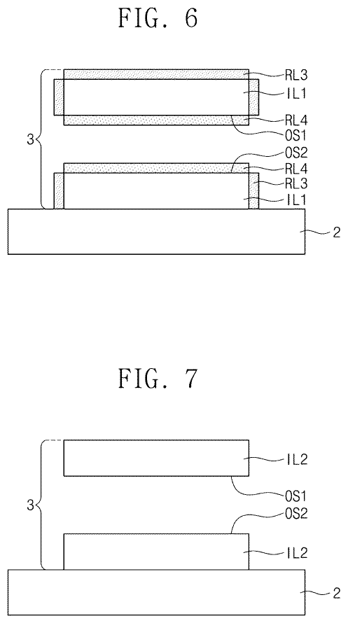

FIG. 2 is a flowchart explaining an atomic layer etching method according to embodiments of the inventive concept. FIG. 3 is a process flow diagram illustrating the atomic layer etching method according to embodiments of the inventive concept. FIGS. 4 to 7 are cross-sectional views illustrating an atomic layer etching method according to embodiments of the inventive concept. More specifically, FIGS. 4 and 5 are cross-sectional views for explaining a first step (S100) of FIG. 2. FIG. 6 is a cross-sectional view for explaining a third step (S300) of FIG. 2. FIG. 7 is a cross-sectional view for explaining a fourth step (S400) of FIG. 2. The atomic layer etching method according to embodiments of the inventive concept may be performed using the atomic layer etching apparatus 1 described with reference to FIG. 1.

First, assuming that the target to be etched by the atomic layer etching apparatus 1 is a substrate including a pattern, the atomic layer etching method according to embodiments of the inventive concept will be briefly described. Referring to FIG. 3, the first step (S100) may be a step of modifying the surface layer of the substrate. The first step (S100) may include a step of adsorbing a first gas onto first surfaces of the substrate and a step of adsorbing a second gas onto second surfaces of the substrate. In this case, the second gas may be supplied after being radicalized by plasma. The second surfaces of the substrate may refer to surfaces except for the first surfaces, which are part of the surfaces of the substrate. For example, the pattern may refer to a hole or a trench. More specifically, the first surfaces may refer to upper surfaces of the substrate. The second surfaces may refer to inner surfaces of the trench.

The second step (S200) may be a purging step. The purging step may mean purging residual reactants of the first step (S100). The third step (S300) may be an etching step of removing the modified surface layer of the substrate. The third step (S300) may include a step in which a portion of the modified surface layer reacts with a third gas, and a step in which the remaining portion of the modified surface layer reacts with a fourth gas. In other words, the third step (S300) may include a step of supplying the third gas to the pattern to etch a portion of each of first and second reaction layers, and a step of supplying the fourth gas to the pattern to etch the remaining portions of the first and second reaction layers. In this case, the fourth gas may be a gas supplied after being radicalized by plasma. The fourth step (S400) may be a purging step. The purging step may mean purging residual reactants of the third step (S300).

In another example, the pattern may include a plurality of three-dimensional structures spaced apart from each other on the substrate. In this case, the inner surfaces of the pattern may refer to surfaces facing each other among three-dimensional structures adjacent to each other. Hereinafter, assuming that the atomic layer etching apparatus 1 etches the three-dimensional structures 3 on the substrate 2, the atomic layer etching method according to embodiments of the inventive concept will be described in more detail. As described with reference to FIG. 1, the three-dimensional structures 3 may be components of a three-dimensional semiconductor device provided on the substrate 2. In addition, the arrangement and number of the three-dimensional structures 3 may vary as needed, however, for convenience of description, it is assumed that two three-dimensional structures 3 are laminated on the substrate 2 spaced apart from each other in a direction perpendicular to the substrate 2. The three-dimensional structures 3 may include a metal or a metal compound. For example, the three-dimensional structures 3 may include at least one of copper (Cu), chromium (Cr), nickel (Ni), aluminum (Al), or other metals, or alloys thereof. In another example, the three-dimensional structures 3 may include silicon (Si) and a semiconductor material.

Referring to FIGS. 2 to 7, the atomic layer etching method according to embodiments of the inventive concept may include: a first step (S100) of modifying surface layers of the three-dimensional structures 3; a second step (S200) of removing first residual reactants; a third step (S300) of etching the surface layers of the three-dimensional structures; and a fourth step (S400) of removing second residual reactants.

The first step (S100) may include: a step of providing the three-dimensional structures 3, which are objects to be etched, to the atomic layer etching apparatus 1; a step of modifying surface layers of the three-dimensional structures with a first gas; and a step of modifying surface layers of the three-dimensional structures with a second gas that has been radicalized. The step of providing the three-dimensional structures to the atomic layer etching apparatus 1 may include providing the substrate 2 and the three-dimensional structures 3 onto the support 110 of the atomic layer etching apparatus 1. The step of modifying surface layers of the three-dimensional structures 3 with the first gas may include providing the first gas into the internal space of the chamber 100 through the first gas inlet 130 and adsorbing the first gas onto the surface layers of the three-dimensional structures 3. The type of substance constituting the first gas may vary depending on the material constituting the three-dimensional structures 3. For example, the first gas may include at least one of O₂, H₂, NH₃, HF, CF₄, NF₃, SF₆, CHF₃, Cl₂, and BCl, however, the inventive concept is not limited thereto. The first gas may be adsorbed onto the three-dimensional structures 3 and may modify surface layers of the three-dimensional structures 3. The step of modifying the surface layers of the three-dimensional structures 3 with the first gas may further include a heat treatment process, as needed. The heat treatment process may be performed after the first gas is provided into an internal space of the chamber 100. The heat treatment process may promote a reaction between the first gas and the three-dimensional structures 3.

More specifically, referring to FIG. 4, the first gas may react with the three-dimensional structures 3 to form a modified first reaction layer RL1 and an unmodified first internal layer IL1. The first gas may modify at least a portion of the surface layers of the three-dimensional structures 3. More specifically, the first gas may modify surface layers of the three-dimensional structures 3 except for the surface layers located between the three-dimensional structures 3. As the two three-dimensional structures 3 are spaced apart and laminated in a direction perpendicular to the substrate 2, a first surface layer OS1 of one of the three-dimensional structures 3 may face a second surface layer OS2 of the other three-dimensional structures 3. In the present specification, the surface layers between the three-dimensional structures 3 may refer to the first surface layer OS1 and the second surface layer OS2. A distance between the first surface layer OS1 and the second surface layer OS2 may be relatively narrow. For example, the distance between the first surface layer OS1 and the second surface layer OS2 may be in a range of about 10 nm to about 20 nm. Accordingly, it may be difficult for the first gas to flow between the first surface layer OS1 and the second surface layer OS2 and to be adsorbed onto the first surface layer OS1 and the second surface layer OS2. In other words, in FIG. 4, the portions of the surface layers modified by the first gas may refer to surface layers of the three-dimensional structures 3 except for the first surface layer OS1 and the second surface layer OS2. In FIG. 1, it is described that the first gas modifies the surface layers of the three-dimensional structures 3 except for the first surface layer OS1 and the second surface layer OS2. However, the inventive concept is not limited thereto, and the surface layers of the three-dimensional structures 3 onto which the first gas is adsorbed may vary. The step of modifying the surface layers of the three-dimensional structures 3 with the first gas may be performed at the first pressure. The first pressure may be in a range of about 10⁰ Torr to about 10¹ Torr. The step of modifying the surface layers of the three-dimensional structures 3 with the first gas may be performed at the first temperature. In the present specification, the first temperature may refer to a certain temperature range rather than a specific temperature. The first temperature may be in a range of about 200° C. to about 600° C., however the inventive concept is not limited thereto.

The step of modifying the surface layers of the three-dimensional structures 3 with the second gas may include radicalizing the second gas supplied through the second gas inlet 150 by the plasma generation part 140; providing the radicalized second gas into an internal space of the chamber 100; and adsorbing the second gas onto the surface layers of the three-dimensional structures 3. The type of substance constituting the radicalized second gas may vary depending on the material constituting the three-dimensional structures 3. For example, the radicalized second gas may include at least one of F* and Cl*; however, the inventive concept is not limited thereto. The step of modifying the surface layers of the three-dimensional structures 3 with the second gas may further include a heat treatment process, as needed. The heat treatment process may be performed after the second gas is provided into the internal space of the chamber 100.

More specifically, referring to FIG. 5, the radicalized second gas may react with the three-dimensional structures 3 to form a modified second surface layer RL2. The radicalized second gas may be adsorbed onto the three-dimensional structures 3 and may modify the remaining surface layers of the three-dimensional structures 3. The remaining surface layers may refer to surface layers of the three-dimensional structures 3 that were not modified by the first gas. In FIG. 5, the remaining surface layers may refer to the first surface layer OS1 and the second surface layer OS2. Since the second gas is radicalized and supplied into the internal space of the chamber 100, the radicalized second gas may have higher reactivity than the first gas. Accordingly, the first surface layer OS1 and the second surface layer OS2, which were difficult to adsorb by the first gas, may be modified by the radicalized second gas. The step of modifying surface layers of the three-dimensional structures 3 with the second gas may be performed at the second pressure. The second pressure may be relatively lower than the first pressure. For example, the second pressure may be in a range of 10⁻³ Torr to 10⁻⁴ Torr. The step of modifying surface layers of the three-dimensional structures 3 with the second gas may be performed at the second temperature. The second temperature may be in a range of about 20° C. to about 600° C., however the inventive concept is not limited thereto. For example, the second temperature may be the same as the first temperature. More specifically, the step of modifying surface layers of the three-dimensional structures 3 with the first gas and the step of modifying surface layers of the three-dimensional structures 3 with the second gas may be performed in the same temperature range. Accordingly, an atomic layer etching method with a simplified process may be provided.

The second step (S200) may be a purging step. In other words, the second step (S200) may include a first purging process. The first purging process may include injecting an inert gas into the chamber 100 and exhausting first residual reactants out of the chamber 100. Injecting the inert gas into the chamber 100 may be performed through the first gas inlet 130 or the second gas inlet 150. Exhausting the first residual reactants may be performed through a pump of the first pressure controller 160 or the second pressure controller 170. In the present specification, the first residual reactants may refer to: the first and second gases that did not react with the three-dimensional structures 3; by-products generated by the reaction of the first gas with the three-dimensional structures 3; and by-products generated by the reaction of the radicalized second gas with the three-dimensional structures 3. The first residual reactants may be exhausted out of the chamber 100 through the first pressure controller 160 or the second pressure controller 170.

The third step (S300) may include a step of etching surface layers of the three-dimensional structures 3 with a third gas and a step of etching surface layers of the three-dimensional structures 3 with a fourth gas. The step of etching surface layers of the three-dimensional structures 3 with the third gas may include providing the third gas into an internal space of the chamber 100 through the first gas inlet 130 and adsorbing the third gas onto surface layers of the three-dimensional structures 3. The type of substance constituting the third gas may vary depending on the material constituting the three-dimensional structures 3. For example, the third gas may include at least one of O₂, H₂, NH₃, HF, CF₄, NF₃, SF₆, CHF₃, Cl₂, and BCl₃, but the inventive concept is not limited thereto. For example, the type of substance constituting the third gas may be the same as that of the first gas. The third gas may be adsorbed onto the three-dimensional structures 3 and may etch a portion of the surface layers of the three-dimensional structures 3. The step of etching surface layers of the three-dimensional structures 3 with the third gas may further include a heat treatment process, as needed. The heat treatment process may be performed after the third gas is provided into the internal space of the chamber 100. The heat treatment process may promote a reaction between the third gas and the three-dimensional structures 3.

More specifically, referring to FIG. 6, the third gas may react with at least a portion of the surface layers of the three-dimensional structures 3. More specifically, the third gas may react with the first reaction layer RL1 of the three-dimensional structures 3. The third gas may react with the three-dimensional structures 3 to convert the first reaction layer RL1 into a third reaction layer RL3. For example, the third gas may be adsorbed onto the first reaction layer RL1 and may form volatile byproducts and reaction products. In other words, the third gas may form volatile species including some atoms of the surface layers of the three-dimensional structures 3 from the first reaction layer RL1. For example, the third gas may react with surface layers of the three-dimensional structures 3 other than the surface layers located between the three-dimensional structures 3. For example, the third gas may react with surface layers except for the first surface layer OS1 and the second surface layer OS2. The third gas may have difficulty flowing between the first surface layer OS1 and the second surface layer OS2 and reacting with the second reaction layer RL2. The step of etching surface layers of the three-dimensional structures 3 with the third gas may be performed at the first pressure and the first temperature. The first pressure may be in a range of about 10⁰ Torr to about 10¹ Torr. The first temperature may be in a range of about 200° C. to about 600° C.

The step of etching surface layers of the three-dimensional structures 3 with a fourth gas may include: radicalizing the fourth gas supplied through the second gas inlet 150 by the plasma generation part 140; providing the radicalized fourth gas into an internal space of the chamber 100; and adsorbing the fourth gas onto the surface layers of the three-dimensional structures 3. The type of substance constituting the radicalized fourth gas may vary depending on the material constituting the three-dimensional structures 3. For example, the radicalized fourth gas may include at least one of F* and Cl*; however, the inventive concept is not limited thereto. For example, the type of substance constituting the fourth gas may be the same as that of the second gas. The step of etching surface layers of the three-dimensional structures 3 with the fourth gas may further include a heat treatment process, as needed. The heat treatment process may be performed after the fourth gas is provided into the internal space of the chamber 100. The heat treatment process may promote a reaction between the third gas and the substrate 2.

The radicalized fourth gas may react with a portion of the surface layers of the three-dimensional structures 3. More specifically, the radicalized fourth gas may react with remaining surface layers of the three-dimensional structures 3 that were not adsorbed by the third gas. For example, the radicalized fourth gas may react with the second reaction layer RL2 of the three-dimensional structures 3. The radicalized fourth gas may react with the three-dimensional structures 3 to convert the second reaction layer RL2 into a fourth reaction layer RL4. For example, the radicalized fourth gas may be adsorbed onto the second reaction layer RL2 to form the fourth reaction layer RL4, and the fourth reaction layer RL4 may include volatile byproducts and reaction products. The volatile byproducts may contain atoms constituting the surface layers of the three-dimensional structures 3 to be etched. In other words, the fourth gas may form volatile species including some atoms of the surface layers of the three-dimensional structures 3 from the second reaction layer RL2. Since the fourth gas is radicalized and supplied into the internal space of the chamber 100, the radicalized fourth gas may have higher reactivity than the third gas. Accordingly, the second reaction layer RL2, where the third gas was difficult to be adsorbed, may be modified by the radicalized fourth gas. The step of etching surface layers of the three-dimensional structures 3 with the fourth gas may be performed at the second pressure. The second pressure may be relatively lower than the first pressure. For example, the second pressure may be in a range of about 10⁻³ Torr to about 10⁻⁴ Torr. The step of modifying surface layers of the three-dimensional structures 3 with the second gas may be performed at the second temperature. The second temperature may be in a range of about 20° C. to about 600° C., however the inventive concept is not limited thereto. For example, the second temperature may be the same as the first temperature. More specifically, the step of etching surface layers of the three-dimensional structures 3 with the third gas may be performed in the same temperature range as the step of etching surface layers of the three-dimensional structures 3 with the fourth gas.

The fourth step (S400) may be a purging step. In other words, the fourth step (S400) may include a second purging process. The second purging process may include injecting an inert gas into the chamber 100 and exhausting second residual reactants. Injecting the inert gas into the chamber 100 may be performed through the first gas inlet 130 or the second gas inlet 150. Exhausting the second residual reactants may be performed through a pump of the first pressure controller 160 or the second pressure controller 170. In the present specification, the second residual reactants may refer to: third and fourth gases that did not react with the three-dimensional structures 3; a third reaction layer RL3 formed by the reaction between the third gas and the three-dimensional structures 3; and a fourth reaction layer RL4 formed by the reaction between the radicalized fourth gas and the three-dimensional structures 3. The second residual reactants may be exhausted out of the chamber 100 through the first pressure controller 160 or the second pressure controller 170. In other words, the third reaction layer RL3 and the fourth reaction layer RL4 may be removed from the three-dimensional structures 3. As volatile byproducts and reaction products including atoms constituting the surface layers of the three-dimensional structures 3 are removed, the surface layers of the three-dimensional structures 3 may be etched.

In FIG. 2, the third step (S300) of etching surface layers of the three-dimensional structures 3 and the fourth step (S400) of removing second residual reactants are illustrated separately. However, the fourth step (S400) may be a portion of the step of etching surface layers of the three-dimensional structures 3. In other words, the third step (S300) and the fourth step (S400) may together constitute a single step of removing modified surface layers of the three-dimensional structures 3, which are the etching target.

The first to fourth steps (S100, S200, S300 and S400) may be repeatedly performed in sequence. The first step (S100) to the fourth step (S400) correspond to one cycle of the atomic layer etching method according to embodiments of the inventive concept. A total number of cycles N may be determined based on a thickness L of the surface layer to be removed from the etching target and a thickness M removed by one cycle (N=L/M). More specifically, the one cycle may include an adsorption cycle and a removal cycle. In this case, the first step (S100) may correspond to the adsorption cycle. The third step (S300) and the fourth step (S400) may correspond to the removal cycle. Between the adsorption cycle and the removal cycle, the second step (S200) of purging residual reactants of the first gas and the radicalized second gas may be performed.

In FIG. 6, it is described that the third gas reacts with the first reaction layer RL1 of the three-dimensional structures 3, and the fourth gas reacts with the second reaction layer RL2 of the three-dimensional structures 3. However, the inventive concept is not limited thereto. The third gas may etch a portion of each of the first reaction layer RL1 and the second reaction layer RL2 of the three-dimensional structures 3. The fourth gas may etch the remaining portions of the first reaction layer RL1 and the second reaction layer RL2 of the three-dimensional structures 3.

In addition, in FIG. 4, since the etching target is limited to the three-dimensional structures 3, it is described that the first gas modifies surface layers of the three-dimensional structures 3 except for the first surface layer OS1 and the second surface layer OS2, however, the inventive concept is not limited thereto. The surface layers to which the first gas is adsorbed may vary depending on the type of etching target. For example, when the etching target includes at least one of a hole, an internal space, or a trench, the surface layers onto which the second gas is adsorbed may refer to inner surfaces of the hole, the internal space, and the trench, where the first gas has difficulty being adsorbed. That is, in the atomic layer etching method according to embodiments of the inventive concept, since the second gas reacts with the surface layers that were not adsorbed by the first gas, the entire surface of the etching target may be etched uniformly.

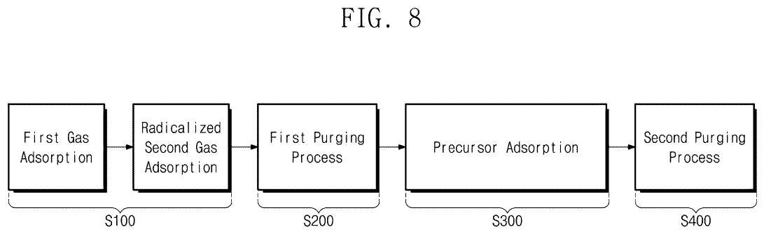

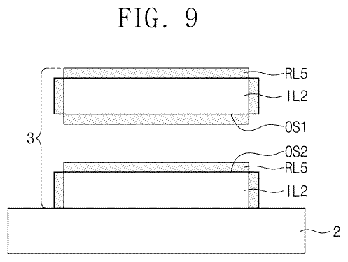

In FIGS. 3, 6, and 7, the third step (S300) is described as including both the step of etching surface layers of the three-dimensional structures 3 with the third gas and the step of etching surface layers of the three-dimensional structures 3 with the fourth gas. However, the inventive concept is not limited thereto. FIG. 8 is a process flow diagram illustrating the atomic layer etching method according to embodiments of the inventive concept. FIG. 9 is a cross-sectional view illustrating an atomic layer etching method according to embodiments of the inventive concept. More specifically, FIG. 9 is a cross-sectional view for explaining the third step (S300) of FIG. 8. Referring to FIGS. 8 and 9, the third step (S300) may include a step of providing a fifth gas, which is generated by vaporizing a precursor into the atomic layer etching apparatus 1, to etch surface layers of the three-dimensional structures 3. The type of substance constituting the third gas may vary depending on the material constituting the three-dimensional structures 5. For example, the fifth gas may be a gas generated by vaporizing a precursor containing a metal. The fifth gas may include a metal-organic precursor. For example, the fifth gas may include at least one of TMA (Trimethyl Aluminum), TTIP (Titanium Tetra-Isopropoxide), TEMAT (Tetrakis(ethylmethylamino)titanium), TEMAZ (Tetrakis(ethylmethylamino)zirconium), TEMAH (Tetrakis(ethylmethylamino)hafnium), DMAC (Dimethylacetamide), and Hacac (acetylacetone); however, the inventive concept is not limited thereto.

The step of providing the fifth gas to etch surface layers of the three-dimensional structures 3 may further include a heat treatment process, as needed. The heat treatment process may be performed after the fifth gas is provided into an internal space of the chamber 100. The heat treatment process may promote a reaction between the third gas and the three-dimensional structures 5.

The fifth gas may react with surface layers of the three-dimensional structures 3. The fifth gas may be adsorbed onto the surface layers of the three-dimensional structures 3. More specifically, the fifth gas may react with the first reaction layer RL1 and the second reaction layer RL2 of the three-dimensional structures 3. The fifth gas may react with the three-dimensional structures 3 to convert the first reaction layer RL1 and the second reaction layer RL2 into a fifth reaction layer RL5. For example, the fifth gas may form volatile byproducts and reaction products. In other words, the fifth gas may form volatile species including some atoms of the surface layers of the three-dimensional structures 3 from the first reaction layer RL1 and the second reaction layer RL2. Subsequently, the fourth step (S400), including the second purging process, may be performed. Through the second purging process, the fifth gas that did not react with the three-dimensional structures 3 and the fifth reaction layer RL5 formed by the reaction between the fifth gas and the three-dimensional structures 3 may be removed. As the volatile byproducts and the reaction products including atoms constituting the surface layers of the three-dimensional structures 3 are removed, the surface layers of the three-dimensional structures 3 may be etched.

According to the atomic layer etching method, since the reaction gas injection step and the radical injection step are alternately performed, the atomic layer of the semiconductor device may be uniformly and effectively modified and etched even when the semiconductor device has a complex 3D structure.

Although the embodiment of the inventive concept is described with reference to the accompanying drawings, those with ordinary skill in the technical field of the inventive concept pertains will be understood that the inventive concept can be carried out in other specific forms without changing the technical idea or essential features. Thus, the above-disclosed embodiments are to be considered illustrative and not restrictive.

What is claimed is:

1. An atomic layer etching method comprising:
a step of providing a substrate;
a modification step of modifying a surface layer of the substrate; and
an etching step of removing the modified surface layer of the substrate,
wherein the modification step comprises:
a step of adsorbing a first gas onto the substrate; and
a step of adsorbing a second gas onto the substrate,
wherein the second gas is supplied after being radicalized by plasma.

2. The atomic layer etching method of claim 1, further comprising a purging step performed before the etching step,
wherein the purging step comprises purging residual reactants of the modification step.

3. The atomic layer etching method of claim 2, wherein the modification step, the purging step, and the etching step are repeatedly performed in sequence.

4. The atomic layer etching method of claim 1, wherein the step of the adsorbing the second gas is performed at a pressure in a range of about 10⁻³ Torr to about 10⁻⁴ Torr.

5. The atomic layer etching method of claim 1, wherein the step of the adsorbing the first gas is performed at a pressure in a range of about 10⁰ Torr to about 10¹ Torr.

6. The atomic layer etching method of claim 1, wherein the first gas comprises at least one of O₂, H₂, NH₃, HF, CF₄, NF₃, SF₆, CHF₃, Cl₂, and BCl₃.

7. The atomic layer etching method of claim 1, wherein the gas radicalized from the second gas comprises at least one of Cl* and F*.

8. The atomic layer etching method of claim 1, wherein the substrate has a pattern, wherein the pattern comprises a plurality of three-dimensional structures spaced apart from each other on the substrate,
in the modification step, the first gas modifies a portion of surfaces of the pattern, and
in the modification step, the second gas modifies remaining surfaces of the pattern.

9. The atomic layer etching method of claim 8, wherein the remaining surfaces of the pattern comprise facing surfaces of two three-dimensional structures adjacent to each other among the three-dimensional structures.

10. The atomic layer etching method of claim 1, wherein the etching step comprises:
a step of injecting a third gas to react with a portion of the modified surface layer; and
a step of injecting a fourth gas to react with a remaining portion of the modified surface layer,
wherein the fourth gas is supplied after being radicalized by plasma.

11. The atomic layer etching method of claim 1, wherein the etching step comprises injecting a fifth gas to etch the modified surface layer,
wherein the fifth gas comprises a gas generated by vaporizing a precursor.

12. An atomic layer etching method comprising:
a step of providing a substrate into a chamber; and
a step of etching first and second surfaces of the substrate,
wherein the step of the etching the first and second surfaces of the substrate comprises an adsorption cycle and a removal cycle,
wherein the adsorption cycle comprises:
a step of adsorbing a first gas onto the first surfaces of the substrate to form a first reaction layer; and
a step of adsorbing a second gas onto the second surfaces of the substrate to form a second reaction layer, and
wherein the removal cycle comprises:
a step of supplying a third gas to the substrate to etch part of the first and second reaction layers; and
a step of supplying a fourth gas to the substrate to etch remaining parts of the first and second reaction layers,
wherein the second gas and the fourth gas are radicalized gases, and
the step of the forming the second reaction layer is performed at a pressure lower than that in the step of the forming the first reaction layer.

13. The atomic layer etching method of claim 12, wherein the substrate has a pattern comprising at least one trench.

14. The atomic layer etching method of claim 13, wherein the first surfaces comprise a top surface of the substrate, and the second surfaces comprise inner surfaces of the trench.

15. The atomic layer etching method of claim 12, wherein the substrate has a pattern, wherein the pattern comprises a plurality of three-dimensional structures spaced apart from each other on the substrate, and
the three-dimensional structures are spaced apart from each other and laminated on the substrate.

16. The atomic layer etching method of claim 12, further comprising a step of purging residual reactants of the first and second gases,
wherein the purging step of purging the reactants of the first and second gases is performed between the adsorption cycle and the removal cycle.

17. The atomic layer etching method of claim 12, wherein the first gas and the third gas are non-radicalized gases.
